(19) United States
(12) Patent Application Publication
(10) Pub. No.: US 2004/0256334 A1
(43) Pub. Date: Dec. 23, 2004

(54) Fan rack

(75) Inventor: Kuei-Hua Chen, Taipei (TW)

Correspondence Address: BACON & THOMAS, PLLC, 625 SLATERS LANE, FOURTH FLOOR, ALEXANDRIA, VA, 22314

(73) Assignee: INVENTEC CORPORATION, Taipei (TW)

(21) Appl. No.: 10/600,438

(22) Filed: Jun. 23, 2003

(51) Int. Cl. H05K 7/20

(52) U.S. Cl. 211/41.17; 361/695

(57) ABSTRACT

The present invention discloses a modularized fan rack installed in a reserved space of an electronic equipment for mounting several fans, which comprises a base board, having a hollow installing section with a plurality of fixtures disposed respectively on two corresponding sides, and the distance between any two adjacent fixtures substantially equal to the length of the fan being mounted onto said base board; a ventilation board with a plurality of openings for ventilating air therethrough, disposed on the surface of one end of said base board; two side boards, respectively disposed on both end of said ventilation board adjacent to said base board and on the side away from said base board, thereby the same fan being coupled by any two adjacent fixtures and another fixture being disposed adjacent to said fixture for mounting a fan adjacent to said side boards.

### BACKGROUND OF THE INVENTION

1. Field of the Invention

The present invention relates to a fan rack, more particularly to a modularized fan rack that is installed in a reserved space of electronic equipment for mounting several fans.

2. Description of the Related Art

In general, a traditional server has a computation speed much faster than a general desktop computer, and also includes more components and functions, so that more heat will be accumulated in the housing of a server. Therefore, a server usually requires a plurality of fans to disperse the heat inside the housing or blow the outside cold air into the housing for heat exchange. However, the way of mounting such fans onto the housing uses screws to pass through the penetrating holes of the housing and fix the screws to the predetermined positions of the screws on the housing in order to mount the fans onto the housing.

However, if various interfaces and electronic components are installed in a server having a smaller volume, the space remained for installation is very limited. After the fans are installed, no extra space will be left for installing other components. There is also not enough operating space required for installing interfaces, electronic components, and fans, which makes the installation operation very inconvenient and difficult. Therefore, if each component can be modularized for the installation, it is something everyone hopes for; particularly the modularized fans can expedite the assembling operation time.

In view of the above description, the present inventor herein with many years of practical experience in the design, development, manufacturing and marketing of the related industry overcame the shortcomings of the prior art by performing a series of researches and developments and finally succeeded to invent the present invention. The fan rack of the present invention comprises a base board, a ventilation board, and two side boards to constitute a rack, wherein the base board has an installing section for installing plurality of fans, a plurality of fixtures disposed respectively on both sides of the installing section, such that any two adjacent fixtures are coupled to the same fan to mount a fan onto the base board; the ventilation board disposed on a surface at one end of the base board has a plurality of openings such that the fans can extract or discharge air through those openings; the two side boards respectively disposed on both ends of the base board adjacent to the ventilation board each has a fixture disposed at the position on one end away from the base boar; these fixtures can mount the fans adjacent to the side boards, so that after the fans are installed in the fan rack, the fan rack can be quickly installed into the reserved space of an electronic device.

### SUMMARY OF THE INVENTION

The primary objective of the present invention is to provide a fan rack, which can be modularized and installed in a reserved space of electronic equipment for mounting several fans.

### BRIEF DESCRIPTION OF THE DRAWINGS

Other features and advantages of the present invention will become apparent in the following detailed description of the preferred embodiments with reference to the accompanying drawings, in which:

FIG. 1 is a perspective diagram of the fan rack of the present invention.

FIG. 2 is a perspective diagram of the connection of the fan rack, fans, circuit board, another circuit board, and panel according to the present invention.

FIG. 3 is an illustrative diagram of the assembling of fan rack and the electronic device according to the present invention.

### DETAILED DESCRIPTION OF THE PREFERRED EMBODIMENTS

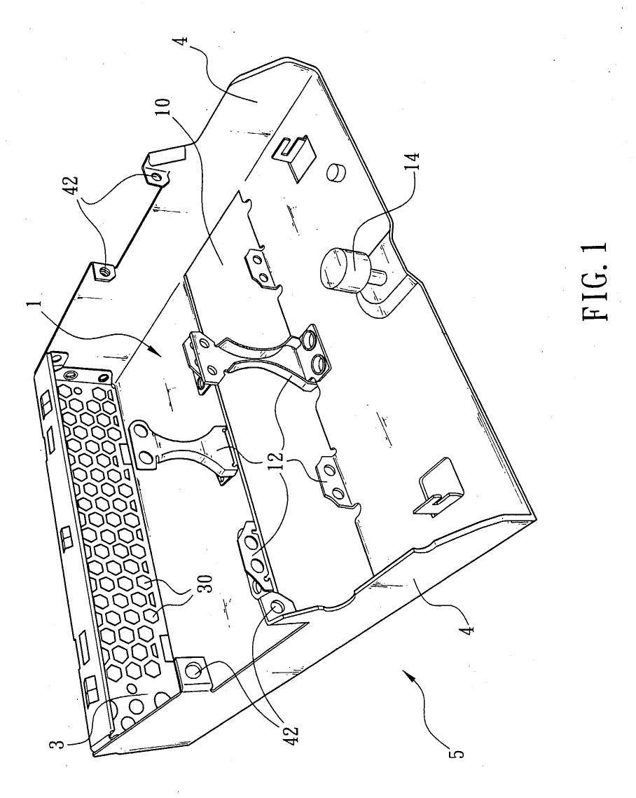

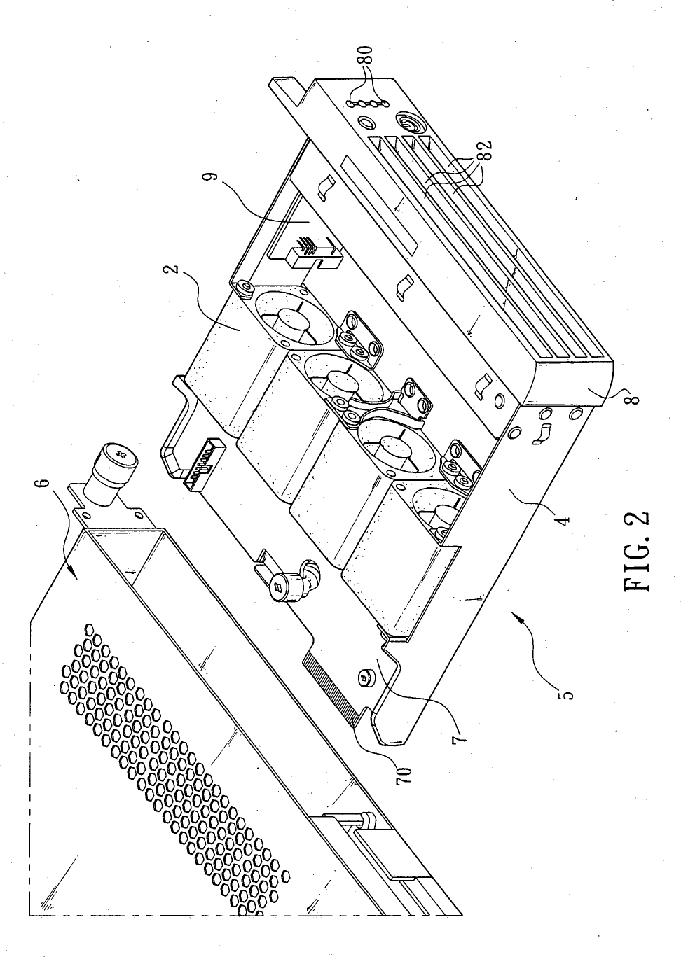

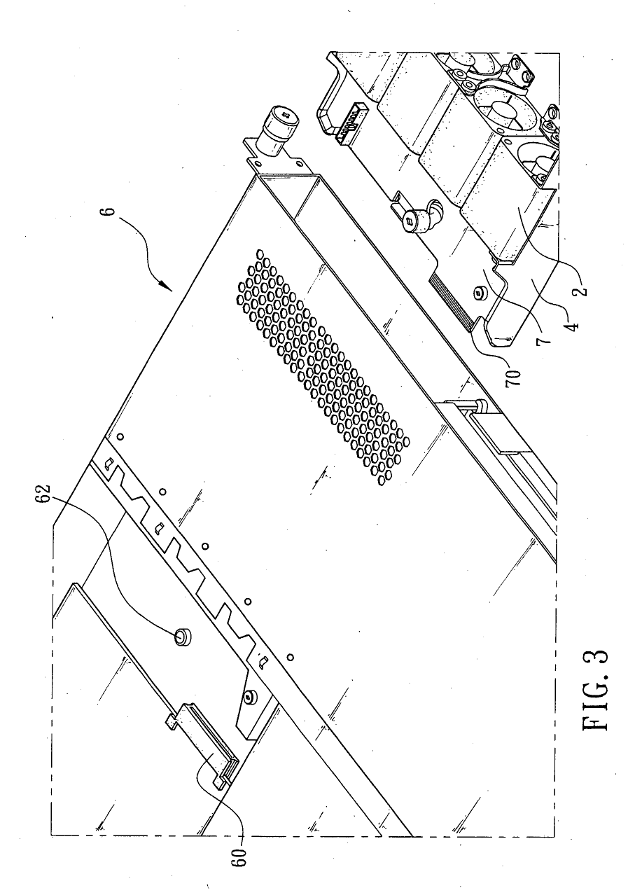

Refer to FIGS. 1 to 3 for the fan rack of the present invention, comprising: a base board 1 having a hollow installing section 10 thereon, and a plurality of fixtures 12 respectively installed on both sides of the installing section 10, and the distance between any two adjacent fixtures 12 exactly equal to the length of an installing fan 2, such that the fan 2 being mounted onto the base board 1 by the fixtures 12; a ventilation board 3 disposed on the surface at one end of the base board 1 and having a plurality of openings 30 such that the fan 2 extracting or discharging air through these openings 30; a side board 4 each disposed on both ends of the ventilation board 3 to constitute a rack 5; another fixture 42 disposed on the position next to the fixtures 12 of the side boards 4 at one side away from the base board 1. The fixtures 42 can mount the fans adjacent to the side boards 4, so that after the fans 2 are installed onto the fan rack 5, the fan rack 5 can be installed quickly into a space reserved in an electronic device 6 (such an the 1U server).

In the present invention, a circuit board 7 is disposed between an end of the base board 1 and the installing section 10 away from the side proximate the ventilation board 3. Such circuit board 7 has a connecting section 70 (such as a gold finger) protruded from the end of the base board 1 and a plurality of electric fixtures (not shown in the figure) for electrically couple the fan 2 to another electric fixture (not shown in the figure) having the electronic components for processing the power supply and the signal received by the connecting section 70. When the fan rack 5 is installed into the electronic device 6, the connecting section 70 exactly couples to another connecting section 60 (such as a gold finger slot) of the electronic device 6, so that the circuit board 7 can receive the signal and power supply come from the electronic device 6, and the circuit board 7 can use the power supply and signal received for effectively controlling the operation and speed of the fan 2.

To make it easier for our examiner to understand the operation of the fans or even the situation of the whole system of the electronic device, refer to FIGS. 1 [symbol] 2 and 3 for the present invention. In the figures, a panel 8 is embedded on the surface of the ventilation board 3; a plurality of light emitting components 80 (such as the LED) are disposed on the panel 8; another circuit board 9 is disposed at a position proximate the light emitting components 80 in the fan rack 5, and such circuit board 7 is coupled to the circuit board 9 through a signal connecting component and the circuit board 9 controls the light emitting condition (such as emitting colored light or blinking several times) of the light emitting components 80 according to the power supply and signal sent by the circuit board 7, such that the user of the electronic device 6 can know the system condition of the electronic device 6 by observing the light emitting condition. Further, a plurality of hollow sections 82 are disposed on the surface of the panel 8, so that the interior of the fan rack 5 can be connected to the outside through the penetrating holes 30 and the hollow section 82. Therefore, the fans 2 can blow the cold air from the outside into the electronic device 6 or extract the hot air in the electronic device 6 to outside.

Since the fan 2 installed in the base board 1 must be mounted on symmetric positions with the fixtures 12 to avoid uneven operation or vibration caused by asymmetric installing positions of the fans 2. Therefore, one of any two adjacent fixtures 12 is corresponsive to two adjacent fans proximate the installing position of the installing section 10, and the other fixture 12 is corresponsive to another two adjacent fans proximate the installing position of the installing section 10; therefore any two adjacent fixtures 12 connects to the diagonal positions of the same fan 2.

In the present invention, a fixing member 14 (such as an elastic screw) is disposed on one end of the base board 1 away from the ventilation board 3, so that when the fan rack 5 is installed into the electronic device 6, the fixing member 14 is corresponsive to the fixed position 62 of the electronic component 6 and the fan rack 5 is then mounted onto the fixed position 62 by the fixing member 14 to fix it in the electronic device 6 and prevent it from separating with the electronic device 6.

By means of the assembling of the above components, the fan rack 5 may be installed outside the electronic device 6. After the installation of the fan is completed, the fan rack 5 is installed in the electronic device 6; Such arrangement can solve the problem that the fan cannot be installed directly inside the electronic device 6. Furthermore, the circuit board 7 inside the fan rack 5 can be used to receive the power supply and signal from the electronic device 6 to control the operation of the fan for appropriately dissipating the heat produced by the electronic device 6, so that the fan 2 will not continue to rotate in the maximum speed in order to extend the life of the fan 2.

While the present invention has been described by the most practical and preferred embodiments, it is understood that this invention is not limited to the disclosed embodiments but is intended to cover various arrangements included within the spirit and scope of the broadest interpretations and equivalent arrangements.

In summation of the above description, the present invention herein enhances the performance than the conventional structure and further complies with the patent application requirements and is submitted to the Patent and Trademark Office for review and granting of the commensurate patent rights.

What is claimed is:

1. A fan rack, comprising:
a base board, having a hollow installing section for installing a plurality of fans, said installing section having a plurality of fixtures disposed respectively on two corresponding sides, and the distance between any two adjacent fixtures substantially equal to the length of the installing fan, such that a fan being mounted onto said base board by any two adjacent fixtures;
a ventilation board, disposed on the surface of one end of said base board, and having a plurality of openings such that air being ventilated through said openings;
two side boards, respectively disposed on both end of said ventilation adjacent to said base board and on the side away from said base board, thereby the same fan being coupled by any two adjacent fixtures and another fixture being disposed adjacent to said fixture for mounting a fan adjacent to said side boards.

2. The fan rack of claim 1, wherein said base board further comprises:
a circuit board, disposed between one end of said base board and one end of said installing section away from the end of said ventilation board, wherein a plurality of another fixtures for electrically coupling with said fixture of said fans, and an electronic component for processing the received power supply and signal;
a connecting section, disposed on the end of said base board protruded from said circuit board, for coupling with another connecting section of an electronic device for receiving the signal and power supply come from said electronic device.

3. The fan rack of claim 1, wherein said ventilation board at its surface has a panel, comprising a plurality of light emitting components, and another circuit board in said fan rack proximate said light emitting components, and said circuit board coupling to another circuit board through a signal connecting component such that the power supply and signal transmitted from said another circuit board being used to control the light emitting condition of said light emitting components.

4. The fan rack of claim 3, wherein said panel at its surface comprises a plurality of hollow sections such that the interior of said fan rack being connected to the outside through said ventilation holes and hollow sections.

5. The fan rack of claim 1, wherein any one of said two adjacent fixtures corresponding to the installing positions of said installing section proximate two adjacent fans, and the other fixture corresponding to the installation positions of said installing section away from said two adjacent fans.

6. The fan rack of claim 1, wherein said base board has a fixing element at one end of said base board away from said ventilation board.

7. The fan rack of claim 3, wherein light emitting component is a light emitting diode (LED).

8. The fan rack of claim 2, wherein said connecting section is a gold finger.

9. The fan rack of claim 2, wherein said electronic device is a server of IU specification.
